(19) United States
(12) Patent Application Publication
(10) Pub. No.: US 2013/0032840 A1
(43) Pub. Date: Feb. 7, 2013

(54) ORGANIC LIGHT EMITTING DEVICES

(71) Applicants: Doo-Hee CHO, Daejeon (KR); Hey Yong Chu, Daejeon (KR); Jeong Ik Lee, Gunpo-si (KR); Jaehyun Moon, Seoul (KR); Jin Wook Shin, Incheon (KR); Jun-Han Han, Daejeon (KR); Jin Woo Huh, Daejeon (KR); Joo Hyun Hwang, Seoul (KR); Chul Woong Joo, Seoul (KR)

(72) Inventors: Doo-Hee CHO, Daejeon (KR); Hey Yong Chu, Daejeon (KR); Jeong Ik Lee, Gunpo-si (KR); Jaehyun Moon, Seoul (KR); Jin Wook Shin, Incheon (KR); Jun-Han Han, Daejeon (KR); Jin Woo Huh, Daejeon (KR); Joo Hyun Hwang, Seoul (KR); Chul Woong Joo, Seoul (KR)

(73) Assignee: ELECTRONICS AND TELECOMMUNICATIONS RESEARCH INSTITUTE, Daejeon (KR)

(21) Appl. No.: 13/483,500

(22) Filed: May 30, 2012

(30) Foreign Application Priority Data
Aug. 2, 2011 (KR) 10-2011-0076929

(51) Int. Cl. H01L 51/52

(52) U.S. Cl. 257/98; 257/E51.019; 257/40

(57) ABSTRACT

Organic light emitting devices are provided. The organic light emitting device may include a substrate having a first refractive index, a first electrode on the substrate, a second electrode disposed between the substrate and the first electrode and having a thickness equal to or greater than one-hundredth of a minimum wavelength of visible light and equal to or smaller than five-hundredths of a maximum wavelength of the visible light, and an organic light emitting layer disposed between the first and second electrodes and having a second refractive index.

### CROSS-REFERENCE TO RELATED APPLICATIONS

This U.S. non-provisional patent application claims priority under 35 U.S.C. §119 to Korean Patent Application No. 10-2011-0076929, filed on Aug. 2, 2011, the entirety of which is incorporated by reference herein.

### BACKGROUND

The inventive concept relates to organic light emitting device and, more particularly, to organic light emitting diode.

Recently, light, small, and inexpensive products have been increasingly demanded in electronic products such as a mobile phone and a note book computer and illumination products. For satisfying the above demands, organic light emitting devices used as display devices and light emitting devices are attractive in the electronic products and the illumination products. Particularly, the organic light emitting devices may be very useful in the electronic products and the illumination products because of lightness, low voltage operation, and low cost thereof.

Recently, various researches have been conducted for increasing light emitting efficiency of the organic light emitting devices. Particularly, various researches have been conducted for organic light emitting devices having high light emitting efficiency by extracting light, which may lost inside the organic light emitting devices, outside the organic light emitting devices.

### SUMMARY

Embodiments of the inventive concept may provide organic light emitting devices having improved light extraction efficiency.

Embodiments of the inventive concept may also provide organic light emitting devices having improved reliability.

In one aspect, an organic light emitting device may include: a substrate having a first refractive index; a first electrode on the substrate; a second electrode disposed between the substrate and the first electrode, the second electrode having a thickness equal to or greater than one-hundredth of a minimum wavelength of visible light and equal to or smaller than five-hundredths of a maximum wavelength of the visible light, and an organic light emitting layer disposed between the first and second electrodes, the organic light emitting layer having a second refractive index, and the first refractive index equal to or greater than the second refractive index.

In some embodiments, each of the first refractive index and the second refractive index may have a range of about 1.6 to about 1.9.

In other embodiments, the second electrode may include a transparent conductive metal oxide thin layer, a conductive organic thin layer, and/or a graphene thin layer.

In still other embodiments, the organic light emitting device may further include: an assistant electrode electrically connected to the second electrode.

In yet other embodiments, the assistant electrode may be disposed between the organic light emitting layer and the second electrode or between the substrate and the second electrode.

In yet still other embodiments, the organic light emitting device may further include: a light scattering layer disposed on the substrate. In this case, the substrate may be disposed between the second electrode and the light scattering layer.

In yet still other embodiments, the light scattering layer may have a plurality of protrusions or a plurality of recess regions.

In yet still other embodiments, the substrate may have a plurality of protrusions or a plurality of recess regions.

In another aspect, an organic light emitting device may include: a substrate having a first refractive index; a first electrode on the substrate; a second electrode disposed between the substrate and the first electrode, the second electrode including a graphene thin layer; an organic light emitting layer disposed between the first and second electrodes, the organic light emitting layer having a second refractive index; and an assistant electrode electrically connected to the second electrode. Here, the first refractive index may be equal to or greater than the second refractive index.

In some embodiments, the assistant electrode may be disposed between the second electrode and the substrate or between the second electrode and the organic light emitting layer.

In other embodiments, the second electrode may have a thickness having a range of one-hundredth of a minimum wavelength of visible light to five-hundredths of a maximum wavelength of the visible light.

In still other embodiments, the assistant electrode may be provided in plural, and the plurality of assistant electrodes may have linear shapes in parallel to each other in a plan view.

In yet other embodiments, the assistant electrode may include first portions in parallel to each other and second portions connecting the first portions in a plan view.

In yet still other embodiments, the organic light emitting device may further include: a light scattering layer disposed on the substrate. The substrate may be disposed between the second electrode and the light scattering layer.

In yet still other embodiments, the light scattering layer may include a mixture of at least two kinds of materials respectively having refractive index different from each other.

In yet still other embodiments, the light scattering layer may include a material having a reflectance lower than that of the substrate.

In yet still other embodiments, the light scattering layer may include a material having a third refractive index, and the third refractive index may be equal to the first refractive index.

In yet still other embodiments, a thickness of the graphene thin layer may have a range of about 5 nm to about 10 nm.

In yet still other embodiments, each of the first refractive index and the second refractive index may have a range of about 1.6 to about 1.9.

### BRIEF DESCRIPTION OF THE DRAWINGS

The inventive concept will become more apparent in view of the attached drawings and accompanying detailed description.

FIG. 1 is a cross-sectional view illustrating an organic light emitting device according to some embodiments of the inventive concept;

FIG. 2 is an enlarged view of a portion ‘A’ of FIG. 1;

FIGS. 3 and 4 are exploded perspective views illustrating organic light emitting devices according to other embodiments of the inventive concept;

FIG. 5A is a cross-sectional view taken along each of a line I-I′ of FIG. 3 and a line II-II′ of FIG. 4;

FIG. 5B is a cross-sectional view illustrating a modified example of an assistant electrode included in an organic light emitting device according to other embodiments of the inventive concept;

FIGS. 6A and 6B are cross-sectional views illustrating modified examples of a substrate included in an organic light emitting device according to other embodiments of the inventive concept; and

FIGS. 7A and 7B are cross-sectional views illustrating modified examples of an organic light emitting device according to some embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

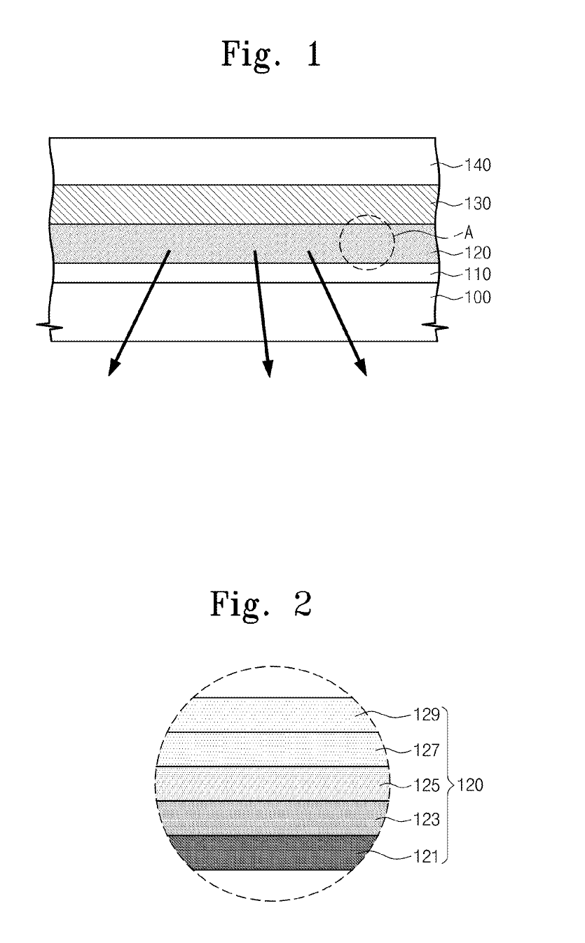

Hereinafter, organic light emitting devices according to embodiments of the inventive concept will be described in detail with reference to the drawings. FIG. 1 is a cross-sectional view illustrating an organic light emitting device according to some embodiments of the inventive concept, and FIG. 2 is an enlarged view of a portion ‘A’ of FIG. 1.

Referring to FIG. 1, an organic light emitting device according to some embodiment includes a substrate 100. The substrate 100 includes a transparent material which is able to transmit light and has a first refractive index. The first refractive index of the substrate 100 may be greater than those of glass, quartz, and plastic. For example, refractive indexes of the glass, the quartz, and the plastic may be about 1.4 to about 1.5, and the first refractive index of the substrate 100 may have a range of about 1.6 to about 1.9. In some embodiments, the substrate 100 may include at least one of borosilicate glass, polyimide, and/or organic/inorganic composite materials.

An anode electrode 110 and a cathode electrode 130 may be disposed on the substrate 100. The anode electrode 110 includes a transparent-conductive material.

In some embodiments, the anode electrode 110 may include a transparent-conductive metal oxide thin layer. For example, the anode electrode 110 may includes an indium tin oxide (ITO) thin layer or an indium zinc oxide (IZO) thin layer. In other embodiments, the anode electrode 110 may include a conductive organic thin layer. For example, the anode electrode 110 may include at least one of conductive organic materials such as copper iodide, polyaniline, poly(3-methylthiophene), and polypyrole. In still other embodiments, the anode electrode 110 may include a graphene thin layer.

The anode electrode 110 may have a thickness equal to or greater than one-hundredth of a minimum wavelength of visible light and equal to or less than five-hundredths of a maximum wavelength of the visible light. The wavelength of the visible light may have a range of about 380 nm to about 780 nm. The thickness of the anode electrode 110 may be equal to or greater than about 3.8 nm which is one-hundredth of about 380 nm corresponding to the minimum wavelength of the visible light. Additionally, the thickness of the anode electrode 110 may be equal to or less than about 39 nm which is five-hundredths of about 780 nm corresponding to the maximum wavelength of the visible light. In other words, the thickness of the anode electrode 110 may have a range of about 3.8 nm to about 39 nm. For example, if the anode electrode 110 is the graphene thin layer, the thickness of the anode electrode 110 may have a range of about 5 nm to about 10 nm.

If a thickness of a layer through which the visible light is transmitted is equal to or greater than one-hundredth of the minimum wavelength of the visible light and equal to or less than five-hundredths of the maximum wavelength of the visible light, existence of the layer may hardly influence a refraction of the transmitted light. In other words, the layer having the thickness of the range of one-hundredth of the minimum wavelength of the visible light to five-hundredths of the maximum wavelength of the visible light may hardly exert optical influence on the light passing through the layer. According to embodiments of the inventive concept, the anode electrode 110 may have the thickness equal to or greater than one-hundredth of the minimum wavelength of the visible light and equal to or less than five-hundredths of the maximum wavelength of the visible light. Thus, it is possible to minimize the effect that the light passing through the anode electrode 110 is reflected or refracted by a surface of the anode electrode 110. As a result, an optical effect influencing the light by the anode electrode 110 may be ignored, and light extraction efficiency of the organic light emitting device may be determined depending on optical characteristics of the substrate 100 and an organic light emitting layer 120.

The anode electrode 110 may be formed by a vacuum deposition method or a sputtering method. If the anode electrode 110 includes the conductive organic thin layer, the anode electrode 110 may be formed by a coating method or an electrolytic polymerization method.

The cathode electrode 130 may include a conductive material having a word function lower than that of the anode electrode 110. For example, the cathode electrode 130 may include at least one of gold, silver, iridium, molybdenum, palladium, and platinum. In some embodiments, the cathode electrode 130 may include a semitransparent conductive material or a reflective conductive material. The cathode electrode 130 may be formed by a vacuum deposition method or a sputtering method.

The organic light emitting layer 120 may be disposed between the anode electrode 110 and the cathode electrode 130. The organic light emitting layer 120 may have a second refractive index. In some embodiments, the first refractive index of the substrate 100 may be equal to or greater than the second refractive index of the organic light emitting layer 120. For example, each of the first refractive index and the second refractive index may have a range of about 1.6 to about 1.9.

When the light generated from the organic light emitting layer 120 is incident on the substrate 100, if a refractive index of the substrate 100 is smaller than that of the organic light emitting layer 120, a part of the light may be total-reflected by the surface of the substrate 100. The light incident on the substrate 100 from the organic light emitting layer 120 follows Snell's law. The Snell's law is represented as the following formula 1.

n1/n2=sin a2/sin a1 (Formula 1)

In the Formula 1, ‘n1’ denotes the second refractive index of the organic light emitting layer, ‘n2’ denotes the first refractive index of the substrate 100, ‘a1’ denotes an incidence angle of the light, and ‘a2’ denotes a refraction angle of the light. According to embodiments of the inventive concept, since the first refractive index is equal to or greater than the second refractive index, the refraction angle of the light is equal to or smaller than the incidence angle of the light. As a result, it is possible to minimize loss of the light may be caused at the surface of the substrate 100 by total reflection. Thus, it is possible to improve the light extraction efficiency of the light passing through the substrate 100.

A passivation layer 140 may be disposed on the cathode electrode 130. The passivation layer 140 may protect the cathode electrode 130. The passivation layer 140 may include a polymer material.

In some embodiments, the organic light emitting layer 120 may be multi-layered. Hereinafter, the multi-layered organic light emitting layer 120 will be described with reference to FIG. 2. FIG. 2 is an enlarged view of a portion ‘A’ of FIG. 1.

Referring to FIG. 2, the organic light emitting layer 120 may include a hole-injection layer 121, a hole-transport layer 123, a light emitting layer 125, an electron-transport layer 127, and an electron-injection layer 129 which are sequentially stacked.

The hole-injection layer 121 may include at least one of copper phthalocyanine (CuPc), TNATA (4,4′,4″-tris[N-(1-naphthyl)-N-phenylamino]-triphenyl-amine), TCTA(4,4′,4″-tris(N-carbazolyl), PEDOT(poly(3,4-ethylenedioxythiophene)), PANI(polyaniline), and PSS(polystyrenesulfonate)

The highest occupied molecular orbital (HOMO) denotes the highest energy level of a valence band, and the lowest unoccupied molecular orbital (LUMO) denotes a lowest energy level of a conduction band.

The hole-injection layer 121 may easily inject holes from the anode electrode 110 into the hole-transport layer 123 by reducing a difference between the work function level of the anode electrode 110 and a HOMO level of the hole-transport layer 123. Thus, a driving current or a driving voltage of the organic light emitting layer 120 may be reduced by the hole-injection layer 121.

The hole-transport layer 123 may include at least one of polymer derivatives including poly(9-vinylcarbazole), polymer derivatives including 4,4′-dicarbazolyl-1,1′-biphenyl(CBP), polymer derivatives including TPD(N,N′-diphenyl-N,N′-bis-(3-methylphenyl)-1,1′-biphenyl-4,4′-diamine), polymer derivatives including NPB (4,4′-bis[N-(1-naphthyl-1-)-N-phenyl-amino]-biphenyl), low molecular weight derivatives including triarylamine, low molecular weight derivatives including pyrazoline, and organic molecules holetransportingmoiety.

The hole-transport layer 123 may provide holes moved through the hole-injection layer 121 to the light emitting layer 125. A HOMO level of the hole-transport layer 123 may be higher than a HOMO level of the light emitting layer 125.

The light emitting layer 125 may include a fluorescent material or a phosphorescent luminescent material. For example, the light emitting layer 125 may include at least one of DPVBi, IDE 120, IDE 105, Alq3, CBP, DCJTB, BSN, DPP, DSB, PESB, PPV derivatives, PFO derivatives, C545t, Ir(ppy)3, and PtOEP. The light emitting layer 125 may be single-layered or multi-layered.

The light emitting layer 125 may generate a first color, a second color, a third color, or a white color. In some embodiments, each of the first to third colors may be one of a red color, a green color, or a blue color. Alternatively, each of the first to third colors may be one of a cyan color, a magenta color, or a yellow color.

The electron-transport layer 127 may include at least one of TPBI(2,2′,2′-(1,3,5-phenylene)-tris[1-phenyl-1H-benzimidazole]), Poly(phenylquinoxaline), 1,3,5-tris[6,7-dimethyl-3-phenyl)quinoxaline-2-yl]benzene(Me-TPQ), polyquinoline,tris(8-hydroxyquinoline)aluminum(Alq3), {6-N,N-diethylamino-1-methyl-3-phenyl-1H-pyrazolo[3,4-b]quinoline}(PAQ-NEt2), and organic molecules including electron transporting moiety.

The electron-injection layer 129 may include a material having high electron mobility. The electron-injection layer 129 may include at least one of lithium (Li), magnesium (Mg), aluminum (Al), calcium (Ca), silver (Ag), and cesium (Cs). For example, the electron-injection layer 129 may include at least one of lithium fluoride (LiF) and cesium fluoride (CsF). The electron-injection layer 129 may perform a function stably supplying electrons to the light emitting layer 125.

When a current is applied to the organic light emitting device according to embodiments of the inventive concept, electrons are moved from the cathode electrode 130 to the light emitting layer 125 and holes are moved from the anode electrode 110 to the light emitting layer 125. The moved electrons and holes are recombined with each other to form excitons. The excitons may be transferred from a high energy level to a low energy level to emit energy. Thus, the light is generated.

In some embodiments, each of the hole-injection layer 121 and the hole-transport layer 123 may have a refractive index within a range of about 1.7 to about 1.9. Additionally, each of the light emitting layer 125, the electron-transport layer 127, and the electron-injection layer 129 may have a refractive index within a range of about 1.6 to about 1.9.

The organic light emitting device according to embodiments of the inventive concept may include the substrate 100 having the refractive index equal to or greater than the refractive index of the organic light emitting layer 130 and the anode electrode 110 disposed between the substrate 100 and the organic light emitting layer 130. Here, the anode electrode 110 has the thickness equal to or greater than one-hundredth of the minimum wavelength of the visible light and equal to or less than five-hundredths of the maximum wavelength of the visible light. When the light generated from the organic light emitting layer 130 passes through the anode electrode 110, the anode electrode 110 may hardly exert optical influence on the light. Thus, when the light is incident on the substrate 100, since the first refractive index of the substrate 100 is equal to or greater than the second refractive index of the organic light emitting layer 130, the refraction angle of the light may be equal to or smaller than the incidence angle of the light at the surface of the substrate 100. As a result, when the light generated from the organic light emitting layer 130 passes through the anode electrode 110 and the substrate 100, it is possible to minimize loss of the light may be caused at an interface between the substrate 100 and the anode electrode 110 by total reflection. And it is possible to improve the light extraction efficiency of the light passing through the substrate 100. Thus, the organic light emitting device with high luminance efficiency and improved reliability may be realized.

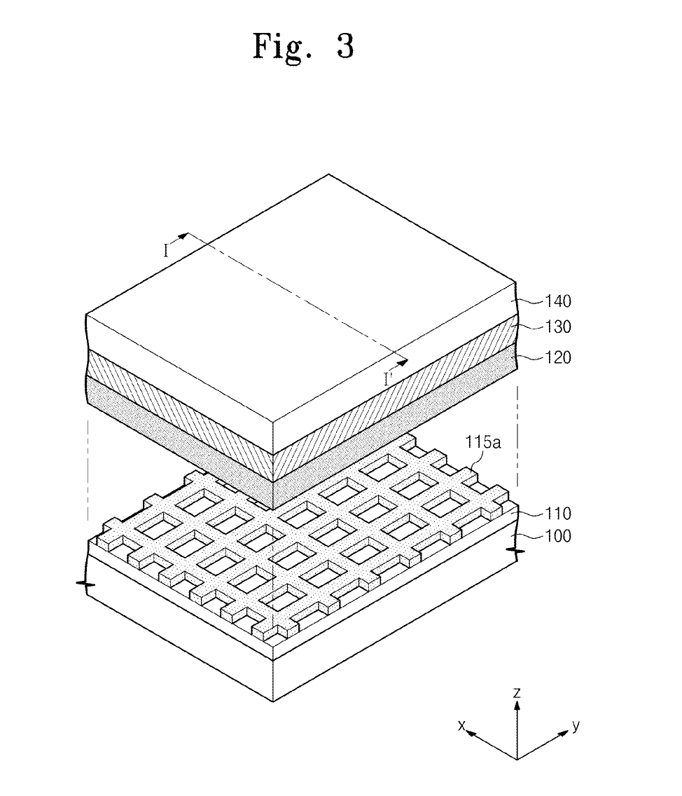

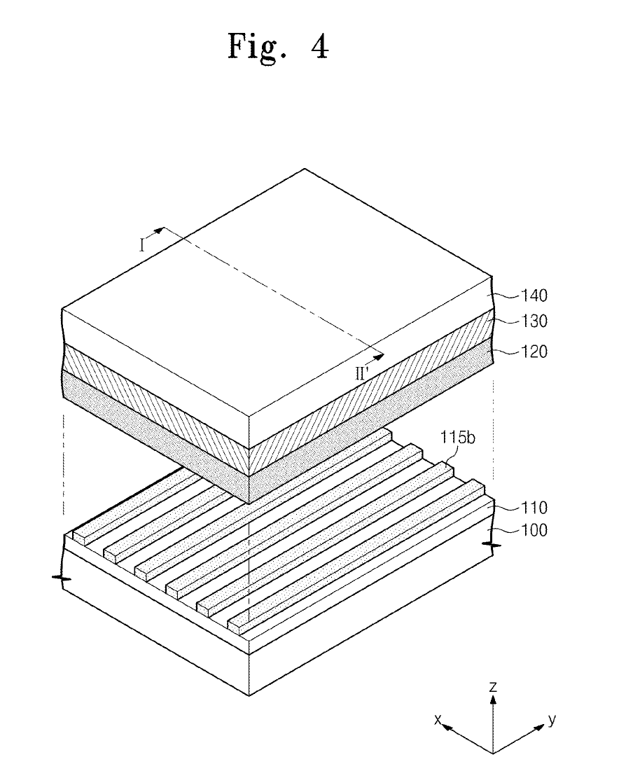

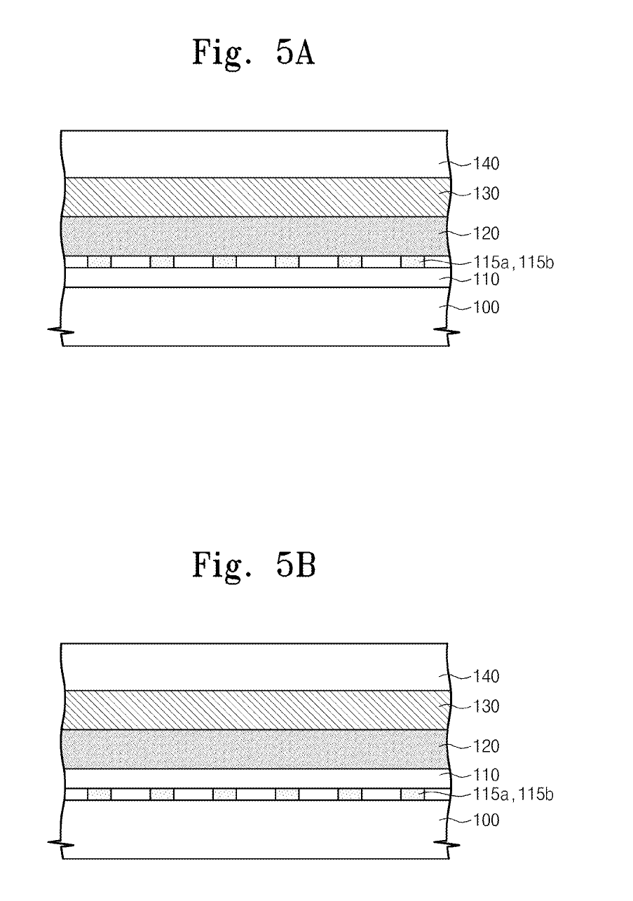

An organic light emitting device according to other embodiments may further include an assistant electrode connected to the anode electrode. The assistant electrode may reduce a sheet resistance of the anode electrode. FIGS. 3 and 4 are exploded perspective views illustrating organic light emitting devices according to other embodiments of the inventive concept, and FIG. 5A is a cross-sectional view taken along each of a line I-I′ of FIG. 3 and a line II-II′ of FIG. 4.

Referring to FIGS. 3 and 5A, an anode electrode 110 and an organic light emitting layer 120 may be disposed on a substrate 100, and an assistant electrode 115a may be disposed between the anode electrode 110 and the organic light emitting layer 120. The assistant electrode 115a may be electrically connected to the anode electrode 110.

The assistant electrode 115a may include a plurality of first portions and a plurality of second portions. The first portions of the assistant electrode 115a may have linear shapes extending in parallel to each other in a first direction. The second portions of the assistant electrode 115a may extend in a second direction to connect the first portions. The second direction may cross the first direction in a plan view. Thus, the assistant electrode 115 may have a mesh-shape having a plurality of openings.

Alternatively, the assistant electrode may have other shapes. Referring to FIG. 4, an assistant electrode 115b may be provided in plural. The plurality of assistant electrodes 115b may have linear shapes spaced apart from each other. The plurality of assistant electrodes 115b may extend in parallel to each other in one direction.

The assistant electrode 115a or 115b may include a metal. For example, the assistant electrode 115a or 115b may include aluminum (Al), gold (Au), silver (Ag), iridium (Ir), molybdenum (Mo), palladium (Pd), platinum (Pt), and/or copper (Cu). The assistant electrode 115a or 115b may be single-layered or multi-layered. For example, the assistant electrode 115a or 115b may include a pair of molybdenum layers and an aluminum layer between the pair of molybdenum layers. Alternatively, the assistant electrode 115a or 115b may be a copper layer. A portion of the substrate 100 covered by the assistant electrode 115a or 115b may be non-transparent, such that an aperture ratio of the organic light emitting device may be reduced. However, the assistant electrode 115a or 115b may reduce the sheet resistance of the anode electrode 110, such that it is possible to improve the luminance efficiency of the organic light emitting device.

Even though not shown in the drawings, an insulating layer may be disposed between the assistant electrode 115a or 115b and the organic light emitting layer 120. The insulating layer may cover the assistant electrode 115a or 115b.

Even though not shown in the drawings, an anti-reflection layer may be disposed on the substrate 100. The anti-reflection layer may minimize reflection of the light outputted to the outside of the organic light emitting device through the substrate 100. Thus, the light extraction efficiency of the light may be improved.

Alternatively, as illustrated in FIG. 5B, the assistant electrode 115a or 115b may be disposed between the substrate 100 and the anode electrode 110. In this case, the assistant electrode 115a or 115b may be electrically connected to the anode electrode 110.

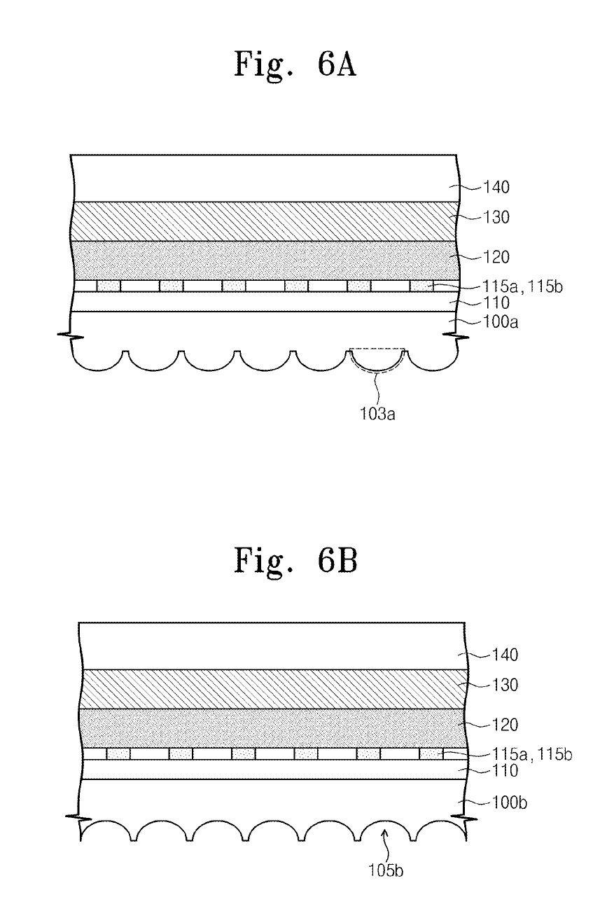

FIGS. 6A and 6B are cross-sectional views illustrating modified examples of a substrate included in an organic light emitting device according to other embodiments of the inventive concept.

Referring to FIG. 6A, an organic light emitting device includes a substrate 100a. The substrate 100a may include one surface adjacent to the anode electrode 110. The substrate 100a may include a plurality of protrusions 103a. The protrusions 103a may protrude from the substrate 100a toward the outside of the substrate 100a. For example, the protrusions 103a may protrude in a direction far away from the one surface of the substrate 100a. In some embodiments, the protrusions 103a may constitute a micro lens array.

When the light generated from the organic light emitting layer 120 is outputted from a substrate to the outside of the organic light emitting device, a part of the light may be total-reflected at an interface of the substrate and an outer air by difference between refractive indexes of the substrate and the outer air. However, as illustrated in FIG. 6A, since the substrate 100a may include the plurality of protrusions 103a, a path of the outputted light may be changed by the protrusions 103a or the outputted light may be scattered by the protrusions 103a. Thus, it is possible to minimize loss of the light may be caused at the interface between the substrate 100a and the outer air by total reflection, and it is possible to improve the light extraction efficiency of the light passing through the substrate 100a.

Alternatively, the substrate may have another shape capable of changing the path of the outputted light or scattering the outputted light. As illustrated in FIG. 6B, a substrate 100b may include a plurality of recess regions 105b. The recess regions 105b may have recessed shapes toward the anode electrode 110. Like the protrusions 103a described with reference to FIG. 6A, the recess regions 105b may change the path of the outputted light or scatter the outputted light. Thus, it is possible to minimize loss of the light may be caused at an interface between the substrate 100b and the outer air by total reflection, and it is possible to improve the light extraction efficiency of the light passing through the substrate 100b.

In other embodiments, the substrate 100 may not have the protrusions or the recess regions of FIG. 6A or 6B. In this case, the substrate 100 may include a light scattering layer formed by mixing at least two kinds of materials which have refractive indexes different from each other, respectively. The light scattering layer may be disposed on an outer surface of the substrate 100, such that the light scattering layer may be exposed externally. Since the light scattering layer has the mixed materials respectively having the refractive indexes different from each other, the light passing through the light scattering layer may be scattered. Thus, it is possible to minimize loss of the light may be caused at an interface between the substrate 100 and the outer air by total reflection, and it is possible to improve the light extraction efficiency of the light passing through the substrate 100. In some embodiments, the light scattering layer may include a material having a reflectance lower than that of the substrate 100.

The substrate 100a and 100b may include a transparent material through which light passes and which has a first refractive index. The first refractive index of the substrate 100a and 100b may be greater than those of glass, quartz, and plastic. For example, refractive indexes of the glass, the quartz, and the plastic may be about 1.4 to about 1.5, and the first refractive index of the substrate 100a and 100b may have a range of about 1.6 to about 1.9. In some embodiments, the substrate 100a and 100b may include at least one of borosilicate glass, polyimide, and/or organic/inorganic composite materials.

The first refractive index of the substrate 100a and 100b may be equal to or greater than the second refractive index of the organic light emitting layer 120. Since the first refractive index is equal to or greater than the second refractive index, when the light generated from the organic light emitting layer 120 is incident on the substrate 100a and 100b, the refraction angle of the light is equal to or smaller than the incidence angle of the light.

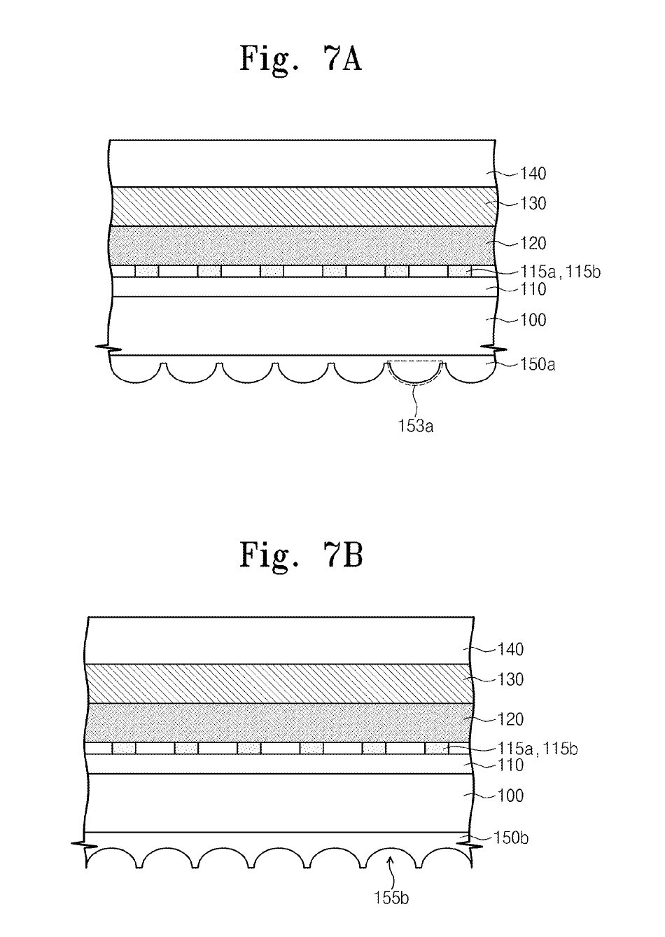

FIGS. 7A and 7B are cross-sectional views illustrating modified examples of an organic light emitting device according to some embodiments of the inventive concept.

Referring to FIG. 7A, an organic light emitting device according modified examples of the inventive concept may include a light scattering layer 150a disposed on a substrate 100. The substrate 100 may have a first surface and a second surface opposite to each other. The first surface of the substrate 100 may be adjacent to an anode electrode 110, and the light scattering layer 150a may be disposed on the second surface of the substrate 100. In other words, the substrate 100 may be disposed between the anode electrode 110 and the light scattering layer 150a.

The light scattering layer 150a may include a plurality of protrusions 153a. The plurality of protrusions 153a may protrude toward the outside of the organic light emitting device. For example, the protrusions 153 may protrude in a direction far away from the substrate 100. In some embodiments, the protrusions 153a may constitute a micro lens array.

When the light generated from the organic light emitting layer 120 is outputted from the substrate 100 to the outside of the organic light emitting device, a part of the light may be total-reflected at an interface of the substrate 100 and the outside by difference between refractive indexes of the substrate 100 and the outside. However, as illustrated in FIG. 7A, since the light scattering layer 150a having the protrusions 153a is disposed on the substrate 100, a path of the light passing through the substrate 100 may be changed by the protrusions 153a or the light may be scattered by the protrusions 153a. Thus, it is possible to minimize loss of the light by total reflection. As a result, it is possible to improve the light extraction efficiency of the light outputted to the outside of the organic light emitting device.

Alternatively, the light scattering layer may have another shape. As illustrated in FIG. 7B, the substrate 100 may have a first surface and a second surface opposite to each other. The first surface of the substrate 100 may be adjacent to the anode electrode 110, and the second surface of the substrate 100 may be adjacent to a light scattering layer 150b. In other words, the substrate 100 may be disposed between the anode electrode 110 and the light scattering layer 150b. The light scattering layer 150b disposed on the substrate 100 may include a plurality of recess regions 155b. The recess regions 155b may have recessed shapes toward the substrate 100. The path of the light transmitted from the substrate 100 may be changed by the recess regions 155b or the light may be scattered by the recess regions 155b. Thus, it is possible to minimize loss of the light by total reflection. As a result, it is possible to improve the light extraction efficiency of the light outputted to the outside of the organic light emitting device.

The light scattering layer 150a or 150b may have a third refractive index. In some embodiments, the third refractive index may be equal to or greater than the first refractive index of the substrate 100. For example, each of the third refractive index and the first refractive index may have a range of about 1.6 to about 1.9. Since the third refractive index is equal to or greater than the first refractive index, an refraction angle of the light incident on the light scattering layer 150a or 150b from the substrate 100 may be equal to or smaller than the incidence angle of the light. Thus, it is possible to minimize loss of the light incident on the light scattering layer 150a or 150b may be caused at an interface between the substrate 100 and the light scattering layer 150a or 150b by total reflection. As a result, it is possible to improve the light extraction efficiency of the light which passes through the light scattering layer 150a or 150b and then is outputted to the outside of the organic light emitting device.

The light scattering layer may have a shape different from those described with reference to FIGS. 7A and 7B. Even though not shown in the drawings, the light scattering layer disposed on the outer surface of the substrate 100 may not have the protrusions 153a and the recess regions 155b of FIGS. 7A and 7B. In this case, the light scattering layer may include a layer formed by mixing at least two kinds of materials which have refractive indexes different from each other, respectively. Since the light scattering layer has the mixed materials respectively having the refractive indexes different from each other, the light passing through the light scattering layer may be scattered. Thus, it is possible to minimize the total reflection caused at an interface between the substrate and the outer air, such that it is possible to improve the light extraction efficiency of the light outputted to the outside from the substrate 100. The light scattering layer may include a material having a reflectance lower than that of the substrate 100.

According to embodiments of the inventive concept, the organic light emitting device may include the substrate having the refractive index equal to or greater than that of the organic light emitting layer. Additionally, the organic light emitting device may also include the transparent electrode having the thickness within a range of one-hundredth of the minimum wavelength of the visible light to five-hundredths of the maximum wavelength of the visible light. Thus, it is possible to minimize refraction or total reflection of the generated light which is caused at the transparent electrode or the interface between the transparent electrode and the substrate. In other words, since the refractive index of the substrate is equal to or greater than that of the organic light emitting layer and the transparent electrode having very thin thickness hardly exerts the optical influence on the generated light, the refraction angle of the light incident on the substrate via the transparent electrode is equal to or smaller than the incidence angle of the light. Thus, the total reflection at the interface of the substrate may be minimized, such that the loss of the light in the organic light emitting device may be minimized. As a result, the light extraction efficiency of the organic light emitting device may be improved.

In a conventional art, a transparent electrode used as an anode may be generally formed to have a thickness of 50 nm or more. In this case, the transparent electrode may sufficiently function as a waveguide. Thus, if a refractive index of a substrate is not equal to or greater than that of the transparent electrode, total reflection may occur at an interface between the transparent electrode and the substrate, light extraction efficiency may be reduced. A material used as the anode may be a transparent conductive metal oxide or graphene. However, a refractive index thereof may be 1.9 or more. Thus, the substrate must have the refractive index of 1.9 or more for minimizing the total reflection. But, it may be actually difficult to provide a transparent substrate having the refractive index of 1.9 or more and satisfying a mechanical characteristic demanded as a substrate. Thus, as described above, if the thickness of the anode is limited to the range of one-hundredth of the minimum wavelength of the visible light to five-hundredths of the maximum wavelength of the visible light, even though the refractive index of the substrate is equal to or greater than the refractive of about 1.6 to about 1.9 of the organic light emitting layer, the total reflection at the interface of the substrate may be minimized. For example, the substrate material having the refractive index of about 1.6 to about 1.9, transparency, and excellent mechanical characteristic may include borosilicate glass, polyimide, and/or organic/inorganic composite materials. Thus, the inventive concept may manufacture the organic light emitting devices having characteristics of excellent light extraction efficiency, low cost, and wide area.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. An organic light emitting device comprising:
a substrate having a first refractive index;
a first electrode on the substrate;
a second electrode disposed between the substrate and the first electrode, the second electrode having a thickness equal to or greater than one-hundredth of a minimum wavelength of visible light and equal to or smaller than five-hundredths of a maximum wavelength of the visible light; and
an organic light emitting layer disposed between the first and second electrodes, the organic light emitting layer having a second refractive index, and the first refractive index equal to or greater than the second refractive index.

2. The organic light emitting device of claim 1, wherein each of the first refractive index and the second refractive index has a range of 1.6 to 1.9.

3. The organic light emitting device of claim 1, wherein the second electrode includes a transparent conductive metal oxide thin layer, a conductive organic thin layer, and/or a graphene thin layer.

4. The organic light emitting device of claim 1, further comprising:
an assistant electrode electrically connected to the second electrode.

5. The organic light emitting device of claim 4, wherein the assistant electrode is disposed between the organic light emitting layer and the second electrode or between the substrate and the second electrode.

6. The organic light emitting device of claim 1, further comprising:
a light scattering layer disposed on the substrate,
wherein the substrate is disposed between the second electrode and the light scattering layer.

7. The organic light emitting device of claim 6, wherein the light scattering layer has a plurality of protrusions or a plurality of recess regions.

8. The organic light emitting device of claim 1, wherein the substrate has a plurality of protrusions or a plurality of recess regions.

9. An organic light emitting device comprising:
a substrate having a first refractive index;
a first electrode on the substrate;
a second electrode disposed between the substrate and the first electrode, the second electrode including a graphene thin layer;
an organic light emitting layer disposed between the first and second electrodes, the organic light emitting layer having a second refractive index; and
an assistant electrode electrically connected to the second electrode,
wherein the first refractive index is equal to or greater than the second refractive index.

10. The organic light emitting device of claim 9, wherein the assistant electrode is disposed between the second electrode and the substrate or between the second electrode and the organic light emitting layer.

11. The organic light emitting device of claim 9, wherein the second electrode has a thickness having a range of one-hundredth of a minimum wavelength of visible light to five-hundredths of a maximum wavelength of the visible light.

12. The organic light emitting device of claim 9, wherein the assistant electrode is provided in plural; and
wherein the plurality of assistant electrodes has linear shapes in parallel to each other in a plan view.

13. The organic light emitting device of claim 9, wherein the assistant electrode includes first portions in parallel to each other and second portions connecting the first portions in a plan view.

14. The organic light emitting device of claim 9, further comprising:
a light scattering layer disposed on the substrate,
wherein the substrate is disposed between the second electrode and the light scattering layer.

15. The organic light emitting device of claim 14, wherein the light scattering layer includes a mixture of at least two kinds of materials respectively having refractive indexes different from each other.

16. The organic light emitting device of claim 14, wherein the light scattering layer includes a material having a reflectance lower than that of the substrate.

17. The organic light emitting device of claim 14, wherein the light scattering layer includes a material having a third refractive index; and
wherein the third refractive index is equal to the first refractive index.

18. The organic light emitting device of claim 9, wherein a thickness of the graphene thin layer has a range of about 5 nm to about 10 nm.

19. The organic light emitting device of claim 9, wherein each of the first refractive index and the second refractive index has a range of about 1.6 to about 1.9.
